(19) United States
(12) Patent Application Publication
(10) Pub. No.: US 2017/0373213 A1
(43) Pub. Date: Dec. 28, 2017

(54) PHOTOVOLTAIC DEVICES WITH IMPROVED N-TYPE PARTNER AND METHODS FOR MAKING THE SAME

(71) Applicant: INTERNATIONAL BUSINESS MACHINES CORPORATION, ARMONK, NY (US)

(72) Inventors: TALIA S. GERSHON, WHITE PLAINS, NY (US); RICHARD A. HAIGHT, MAHOPAC, NY (US); RAVIN MANKAD, YONKERS, NY (US); SAURABH SINGH, NEW YORK, NY (US); TEODOR K. TODOROV, YORKTOWN HEIGHTS, NY (US)

(21) Appl. No.: 15/189,368

(22) Filed: Jun. 22, 2016

(51) Int. Cl. H01L 31/072; H01L 31/0272; H01L 31/0224; H01L 31/18; H01L 31/075

(52) U.S. Cl. CPC H01L 31/072; H01L 31/1884; H01L 31/1864; H01L 31/075; H01L 31/022466; H01L 31/022483; H01L 31/022475; H01L 31/0272

(57) ABSTRACT

A photovoltaic device with an improved n-type partner and a method for making the same. The device includes: a transparent substrate; a transparent conductive electrode layer disposed on the transparent substrate; an n-type layer of Zn₁₋ₓMgₓO, wherein 0<x≦1, disposed on the transparent conductive electrode layer; a chalcogen absorber layer disposed on the n-type layer; and a conductive layer disposed on the chalcogen absorber layer. The method includes: forming a transparent conductive electrode layer on a transparent substrate; forming an n-type layer of Zn₁₋ₓMgₓO, wherein 0<x≦1, on the transparent conductive electrode layer; forming a chalcogen absorber layer on the n-type layer; forming a conductive layer on the chalcogen absorber layer; and annealing to form the device. Another device having a superstrate configuration with the order of the layers reversed and a method for making the same is provided.

### TECHNICAL FIELD OF THE INVENTION

The present invention relates to photovoltaic devices. More particularly, the present invention relates to photovoltaic devices with a chalcogen absorber layer.

### BACKGROUND OF THE INVENTION

Solar panels employ photovoltaic cells to generate current flow. When a photon hits a photovoltaic cell, the photon may be transmitted through, reflected off, or absorbed by the photovoltaic cell if the photon energy is higher than the material band gap value. This generates an electron-hole pair and sometimes heat, depending on the band structure.

A photovoltaic cell can be described in terms of its open circuit voltage (V_{oc}), short circuit current (J_{sc}) and fill factor (FF). Fill factor is the ratio of the maximum power point (Pₘ) divided by the open circuit voltage (V_{oc}) and short circuit current (J_{sc}): FF=Pₘ/V_{oc}J_{sc}. The fill factor is directly affected by the values of the cell's series and shunt resistance. Increasing the shunt resistance (Rₛₕ) and decreasing the series resistance (Rₛ) will lead to a higher fill factor, thus resulting in greater efficiency, and pushing the cells output power closer towards its theoretical maximum.

There are many different materials used to fabricate photovoltaic cells such as CIGS (copper indium gallium selenide), CZTS (copper zinc tin sulfide), or organic polymers. Elemental selenium is the first semiconductor material to be used in a photovoltaic device by Charles Fritts in 1873. However, the initial efficiency was below 1%. Over the years, the best Se cell reported to date has only reached an efficiency up to 5.1% with the structure of: Glass/TiO₂/Se/Au.

### SUMMARY OF THE INVENTION

In one aspect, the present invention provides a photovoltaic device. The photovoltaic device includes: a transparent substrate; a transparent conductive electrode layer disposed on the transparent substrate; an n-type layer of a compound having the formula Zn₁₋ₓMgₓO, wherein 0<x≦1, disposed on the transparent conductive electrode layer; a chalcogen absorber layer disposed on the n-type layer; and a conductive layer disposed on the interlayer.

In another aspect, the present invention provides a method for fabricating a photovoltaic device. The method includes the steps of: forming a transparent conductive electrode layer on a transparent substrate; forming an n-type layer of a compound having the formula Zn₁₋ₓMgₓO, wherein 0≦x≦1, on the transparent conductive electrode layer; forming a chalcogen absorber layer on the n-type layer; forming a conductive layer on the chalcogen absorber layer; and annealing at a temperature, pressure, and length of time sufficient to form the structure of the photovoltaic device.

In another aspect, the present invention further provides another photovoltaic device. This photovoltaic device includes: a transparent superstrate; a conductive layer disposed on the transparent superstrate; a chalcogen absorber layer disposed on the conductive layer; an n-type layer of a compound having the formula Zn₁₋ₓMgₓO, wherein 0≦x≦1, disposed on the chalcogen absorber layer; and a transparent conductive electrode layer disposed on the n-type layer.

The present invention also provides another method for fabricating a photovoltaic device. This method includes the steps of: forming a conductive layer on a transparent superstrate; forming a chalcogen absorber layer on the conductive layer; forming an n-type layer of a compound having the formula Zn₁₋ₓMgₓO, wherein 0≦x≦1, on the chalcogen absorber layer; forming a transparent conductive electrode layer on the n-type layer; and annealing at a temperature, pressure, and length of time sufficient to form the structure of the photovoltaic device.

A more complete understanding of the present invention, as well as further features and advantages of the present invention, will be shown through the following detailed description and drawings.

### BRIEF DESCRIPTION OF THE SEVERAL VIEWS OF THE DRAWINGS

FIG. 1 is a cross-sectional diagram illustrating a transparent conductive electrode layer formed on a substrate according to an embodiment of the present invention.

FIG. 2 is a cross-sectional diagram illustrating an n-type layer formed on the transparent conductive electrode layer according to an embodiment of the present invention.

FIG. 3 is a cross-sectional diagram illustrating a chalcogen absorber layer formed on the n-type layer according to an embodiment of the present invention.

FIG. 4 is a cross-sectional diagram illustrating an optional p-type molybdenum trioxide (MoO₃) interlayer formed on the chalcogen absorber layer according to an embodiment of the present invention.

FIG. 5 is a cross-sectional diagram illustrating a conductive metal layer formed on the p-type interlayer according to an embodiment of the present invention.

FIG. 6 is a cross-sectional diagram illustrating a photovoltaic device in a superstrate configuration formed according to a method of the present invention.

FIG. 7(a) is a diagram illustrating a photovoltaic device having a substrate configuration according to an embodiment of the present invention.

FIG. 7(b) is a diagram illustrating a photovoltaic device having a superstrate configuration according to an embodiment of the present invention.

FIG. 8 is a diagram illustrating the characteristics of different photovoltaic cells with differing n-type partner compositions without aging.

FIG. 9 is a diagram illustrating the characteristics of different photovoltaic cells with differing n-type partner compositions with aging.

### DETAILED DESCRIPTION OF THE PREFERRED EMBODIMENTS

Some preferred embodiments will be described in more detail with reference to the accompanying drawings, in which the preferred embodiments of the present invention have been illustrated. However, the present invention can be implemented in various manners, and thus should not be construed to be limited to the embodiments disclosed herein. On the contrary, those embodiments are provided for the thorough and complete understanding of the present invention, and to completely convey the scope of the present invention to those skilled in the art.

A p-n junction is the boundary or interface between two types of semiconductor material, the n-type and p-type. The “p,” or positive side, contains an excess of electron holes, while the “n,” or negative side, contains an excess of electrons. The p-n junctions is an elementary part of photovoltaic cells since the junction is the active site where the electronic action of the device takes place.

Referring to FIGS. 1-5, an exemplary methodology for fabricating a photovoltaic device with an improved n-type partner is shown. The method includes the steps of: forming a transparent conductive electrode layer 104 on a transparent substrate 102; forming an n-type layer 106 of a compound having the formula Zn₁₋ₓMgₓO, wherein 0<x≦1, on the transparent conductive electrode layer 104; forming a chalcogen absorber layer 108 on the n-type layer 106; forming a conductive layer 112 on the chalcogen absorber layer; and annealing at a temperature, pressure, and length of time sufficient to form the structure of the photovoltaic device. Furthermore, an optional tellurium adhesion layer (not shown) may be deposited on the improved n-type layer 106 before deposition of the chalcogen absorber layer 108 and an optional p-type molybdenum trioxide (MoO₃) interlayer 110 can be formed after deposition of the chalcogen absorber layer 108.

To begin the process, as shown in FIG. 1, a substrate 102 is provided. Suitable substrate materials include, but are not limited to, glass, plastic, ceramic and metal foil (e.g., aluminum, copper, etc.) substrates. As will be described in detail below, it has been found that employing a reflective back contact on the substrate 102 aids in increasing the efficiency of the device. A reflective back contact can be created by forming the back contact, in the manner described below, on a planar substrate (glass or metal foil substrate) or on a polished substrate. Thus, it may be desirable at this stage to polish the substrate, especially in the case of a plastic or ceramic substrate. Polishing of the substrate 102 may be carried out using any mechanical or chemical mechanical process known in the art.

A transparent conductive electrode layer 104 is then formed on the substrate. During operation, the transparent conductive electrode layer 104 is used as an electrode for low resistance electrical contacts without blocking light. According to an exemplary embodiment of the present invention, the transparent conductive electrode 104 is formed from a transparent conductive material, such as fluorine doped tin oxide (FTO), indium doped tin oxide (ITO), aluminum doped zinc oxide (ZnO:Al), or fluorine doped tin dioxide (SnO₂:F). The techniques for forming a transparent conductive electrode from these materials would be apparent to one of skill in the art and thus are not described further herein.

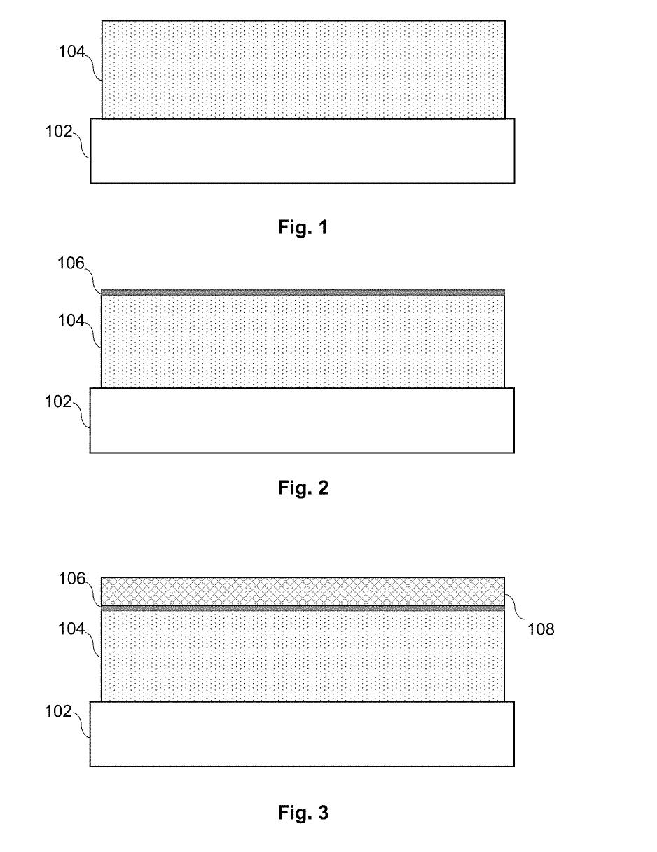

In FIG. 2, according to an exemplary embodiment of the present invention, an improved n-type layer 106 is formed on the transparent conductive electrode layer 104. An n-type layer is usually a material such as titanium dioxide or zinc dioxide. However, in various embodiments of the present invention, a Zn₁₋ₓMgₓO compound is used as the improved n-type layer 106. In embodiments of the present invention, the Zn₁₋ₓMgₓO n-type layer 106 was deposited via sputtering using a 75 watt ZnO gun and a 100 watt MgO gun. The guns were located at a distance of 22.5 centimeters above the substrate and oxygen flow rate was controlled at 1.5 sccm (standard cubic centimeters per minute) for a total deposition time of 9400 seconds. While these were the conditions used for various embodiments of the present invention, the same deposition can be achieved using suitable techniques that would be apparent to one of skill in the art. The improved n-type layer 106 can have a thickness ranging from about 2 nm to about 200 nm with a preferred thickness of about 30 nm to about 60 nm. During operation, the improved n-type layer 106 serves as the electron selective layer to collect electrons.

In FIG. 3, according to an exemplary embodiment of the present invention, a chalcogen absorber layer 108 is formed on the improved n-type layer 106. The chalcogen absorber layer can be any chalcogen such as sulfur, selenium, tellurium or any combination thereof. In various embodiments of the present invention, highly pure selenium (99.999%) is the preferred chalcogen used. The chalcogen absorber layer 108 can be deposited through vacuum evaporation, chemical bath deposition, electrochemical deposition, atomic layer deposition, successive ionic layer absorption and reaction (SILAR), chemical vapor deposition, sputtering, spin coating, doctor blading, physical vapor deposition or any other suitable technique that would be apparent to one of skill in the art. The chalcogen absorber layer 108 has a thickness from about 25 nm to about 200 nm with a preferred thickness of about 80 nm to about 120 nm.

Optionally, a tellurium adhesion layer (not shown) may be deposited on the improved n-type layer 106 before deposition of the chalcogen absorber layer 108. The thickness of the tellurium adhesion layer is very small, for example, about 1 nm and improves the adhesion between the improved n-type layer 106 and the chalcogen absorber layer 108.

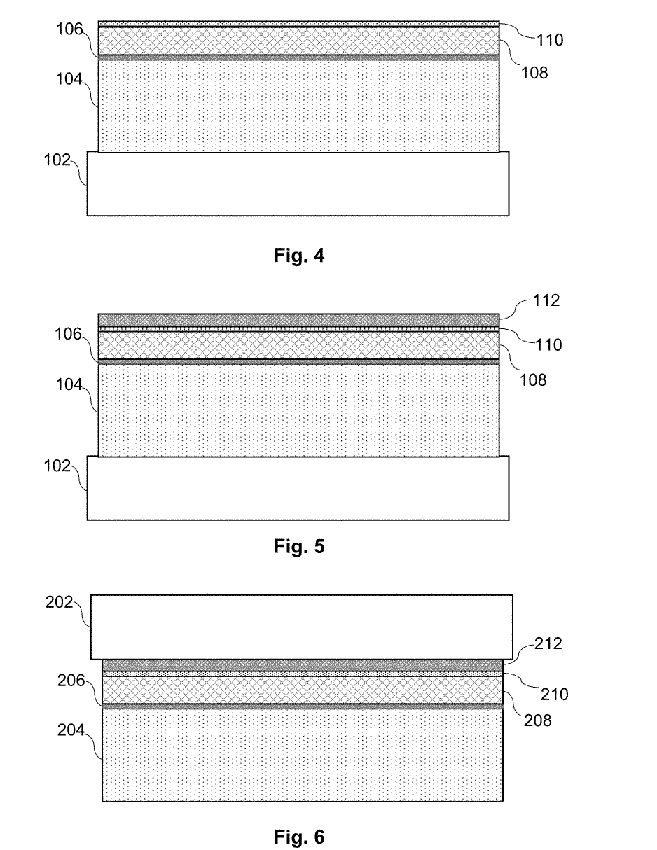

In FIG. 4, according to an exemplary embodiment of the present invention, an optional p-type molybdenum trioxide (MoO₃) interlayer 110 is formed on the chalcogen absorber layer 108. The p-type molybdenum trioxide (MoO₃) interlayer 110 can be deposited through vacuum evaporation, chemical bath deposition, electrochemical deposition, atomic layer deposition, successive ionic layer absorption and reaction (SILAR), chemical vapor deposition, sputtering, spin coating, doctor blading, physical vapor deposition or any other suitable technique that would be apparent to one of skill in the art. The thickness of the p-type molybdenum trioxide (MoO₃) layer 110 is from about 2 nm to about 200 nm with a preferred thickness of about 20 nm to about 60 nm and an optimal thickness of about 20 nm. The optional p-type molybdenum trioxide (MoO₃) interlayer 110 increases the work function of the conductive layer 112. The work function of a metal is the minimum energy needed to remove an electron from a solid to a point in the vacuum immediately outside the solid surface. Here, the p-type molybdenum trioxide (MoO₃) interlayer has a work function of ˜5.3 eV. In photovoltaic cells, increasing the work function of the conductive layer correlates positively to an increase in open circuit voltage (V_{oc}) and short circuit current (J_{sc}).

In FIG. 5, according to an exemplary embodiment of the present invention, a conductive layer 112 is deposited on the p-type interlayer 110. The conductive layer 112 can be: (1) carbon materials such as graphite, graphene, nanotubes; (2) metals and their alloys such as gold, silver, copper, platinum, palladium; Zn, Ni, Co, Mo, Fe V, Cr, Sn, W, Mo, Ti, Mg; and (3) conductive oxides such as fluoride doped tin oxide (FTO), indium doped tin oxide (ITO) and aluminum doped zinc oxide (ZnO:Al). The conductive layer 112 can be deposited through vacuum evaporation, chemical bath deposition, electrochemical deposition, atomic layer deposition, successive ionic layer absorption and reaction (SILAR), chemical vapor deposition, sputtering, spin coating, doctor blading, physical vapor deposition or any other suitable technique that would be apparent to one of skill in the art. The thickness of the conductive layer 112 is preferably from about 2 nm to about 200 nm. The device is annealed at a temperature, pressure, and length of time sufficient to form the structure of the photovoltaic device.

In the alternative, if the p-type interlayer 110 is not being used, then the conductive layer 112 would assume the role of the p-type layer with regard to the p-n heterojunction and the conductive layer would be directly deposited onto the chalcogen absorber layer 108.

In FIG. 6, another embodiment of the present invention is shown where a superstrate is used instead of a substrate. The method for fabricating the superstrate configuration of the present invention includes: forming a conductive layer 212 on a transparent superstrate 202; forming an optional p-type molybdenum trioxide (MoO₃) interlayer 210 on the conductive layer 212; forming a chalcogen absorber layer 208 on the optional p-type molybdenum trioxide (MoO₃) interlayer 210; forming an improved n-type layer 206 on the chalcogen absorber layer 208; forming a transparent conductive electrode layer 204 on the improved n-type layer 206; and annealing at a temperature, pressure, and length of time sufficient to form the structure of the photovoltaic device.

Furthermore, the optional tellurium adhesion layer (not shown) can be deposited on the optional p-type molybdenum trioxide (MoO₃) layer 210 before deposition of the chalcogen absorber layer 208. If the optional p-type molybdenum trioxide (MoO₃) layer 210 is not being used, then the optional tellurium adhesion layer (not shown) can be deposited on the conductive layer 212. If neither optional layer is being used then the chalcogen absorber layer 208 would be deposited on the conductive layer 212 and the improved n-type layer would be deposited onto the chalcogen absorber layer 208.

Suitable superstrate materials include, but are not limited to, glass, plastic, ceramic and metal foil (e.g., aluminum, copper, etc.) superstrates.

The conductive layer 212 can be: (1) carbon materials such as graphite, graphene, nanotubes; (2) metals and their alloys such as gold, silver, copper, platinum, palladium; Zn, Ni, Co, Mo, Fe V, Cr, Sn, W, Mo, Ti, Mg; and (3) conductive oxides such as fluoride doped tin oxide (FTO), indium doped tin oxide (ITO) and aluminum doped zinc oxide (ZnO:Al). The conductive layer 112 can be deposited through vacuum evaporation, chemical bath deposition, electrochemical deposition, atomic layer deposition, successive ionic layer absorption and reaction (SILAR), chemical vapor deposition, sputtering, spin coating, doctor blading, physical vapor deposition or any other suitable technique that would be apparent to one of skill in the art. The thickness of the conductive layer 212 is preferably from about 2 nm to about 200 nm. The device is annealed at a temperature, pressure, and length of time sufficient to form the structure of the photovoltaic device.

The optional p-type molybdenum trioxide (MoO₃) interlayer 210 can be deposited through vacuum evaporation, chemical bath deposition, electrochemical deposition, atomic layer deposition, successive ionic layer absorption and reaction (SILAR), chemical vapor deposition, sputtering, spin coating, doctor blading, physical vapor deposition or any other suitable technique that would be apparent to one of skill in the art. The thickness of the p-type molybdenum trioxide (MoO₃) layer 210 is from about 2 nm to about 200 nm with a preferred thickness of about 20 nm to about 60 nm and an optimal thickness of about 20 nm. If optional p-type molybdenum trioxide (MoO₃) interlayer 210 is not being used, then the conductive layer 212 would take the role as the p-type layer for the p-n heterojunction and the conductive layer 212 would be deposited directly onto the chalcogen absorber layer 208.

The chalcogen absorber layer can be any chalcogen such as sulfur, selenium, tellurium or any combination thereof. In various embodiments of the present invention, highly pure selenium (99.999%) is the preferred chalcogen used. The chalcogen absorber layer 208 can be deposited through vacuum evaporation, chemical bath deposition, electrochemical deposition, atomic layer deposition, successive ionic layer absorption and reaction (SILAR), chemical vapor deposition, sputtering, spin coating, doctor blading, physical vapor deposition or any other suitable technique that would be apparent to one of skill in the art. The chalcogen absorber layer 208 has a thickness from about 25 nm to about 200 nm with a preferred thickness of about 80 nm to about 120 nm.

An n-type layer is usually a material such as titanium dioxide or zinc dioxide. However, in various embodiments of the present invention, a Zn₁₋ₓMgₓO compound is used as an improved n-type layer 206. In embodiments of the present invention, the Zn₁₋ₓMgₓO n-type layer 206 was deposited via sputtering using a 75 watt ZnO gun and a 100 watt MgO gun. The guns were located at a distance of 22.5 centimeters above the substrate and oxygen flow rate was controlled at 1.5 sccm (standard cubic centimeters per minute) for a total deposition time of 9400 seconds. While these were the conditions used for various embodiments of the present invention, the same deposition can be achieved using suitable techniques that would be apparent to one of skill in the art. The improved n-type layer 206 can have a thickness ranging from about 2 nm to about 200 nm with a preferred thickness of about 30 nm to about 60 nm. During operation, the improved n-type layer 206 serves as the electron selective layer to collect electrons.

During operation, the transparent conductive electrode layer 204 is used as an electrode for low resistance electrical contacts without blocking light. According to an exemplary embodiment of the present invention, the transparent conductive electrode 104 is formed from a transparent conductive material, such as fluorine doped tin oxide (FTO), indium doped tin oxide (ITO), aluminum doped zinc dioxide (ZnO₂:Al), or fluorine doped tin dioxide (SnO₂:F). The techniques for forming a transparent conductive electrode from these materials would be apparent to one of skill in the art and thus are not described further herein.

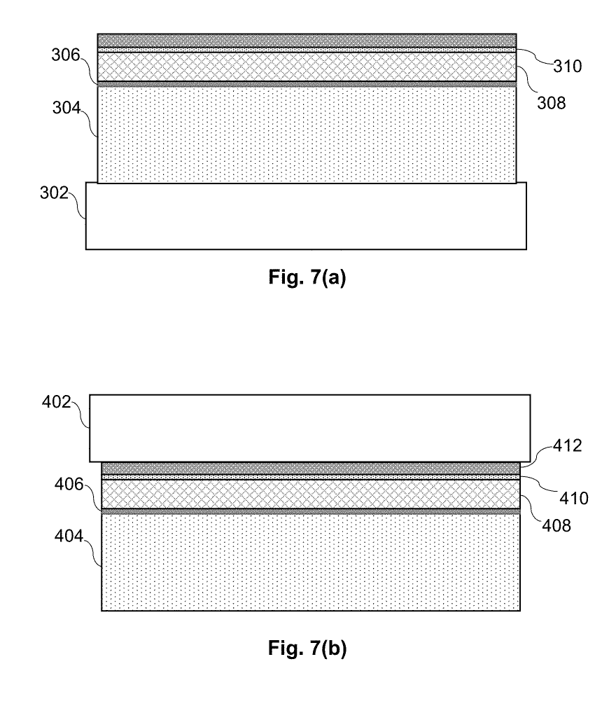

Referring now to FIG. 7(a), a diagram illustrating a photovoltaic device having a substrate configuration according to an embodiment of the present invention is shown. The photovoltaic device includes: a transparent substrate 302; a transparent conductive electrode layer 304 disposed on the transparent substrate 302; an n-type layer 306 of a compound having the formula Zn₁₋ₓMgₓO, wherein 0<x≦1, disposed on the transparent conductive electrode layer 304; a chalcogen absorber layer 308 disposed on the n-type layer 306; and a conductive layer 312 disposed on the chalcogen absorber layer 308. Furthermore, an optional tellurium adhesion layer (not shown) may be disposed on the n-type layer 306 before the chalcogen absorber layer 308 and an optional p-type molybdenum trioxide (MoO₃) interlayer 310 can be disposed on the chalcogen absorber layer 308.

In FIG. 7(b), a diagram illustrating a photovoltaic device having a superstrate configuration according to an embodiment of the present invention is shown. The photovoltaic device includes: a transparent superstrate 402; a conductive layer 412 disposed on the transparent superstrate 402; a chalcogen absorber layer 408 disposed on the conductive layer 412; an n-type layer 406 of a compound having the formula Zn₁₋ₓMgₓO, wherein 0<x≦1, disposed on the chalcogen absorber layer 408; and a transparent conductive electrode layer 404 disposed on the n-type layer 406. Furthermore, an optional tellurium adhesion layer (not shown) may be disposed on the conductive layer 412 before the chalcogen absorber layer 408 and an optional p-type molybdenum trioxide (MoO₃) interlayer 410 can be disposed on the conductive layer 412.

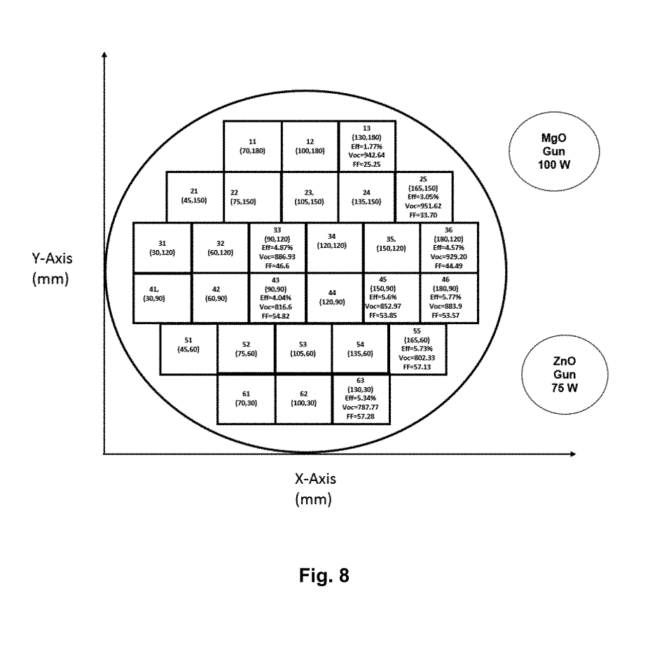

Referring to FIG. 8, a diagram illustrating the characteristics of different photovoltaic cells with differing n-type partner compositions without aging is shown. Each individual square in the diagram shown in FIG. 8 represents a photovoltaic cell fabricated using the method provided in FIGS. 1-5. However, the deposition of the improved n-type partner varies from cell to cell. The cells closer to the Y-Axis have lower concentrations of Zn₁₋ₓMgₓO and the cells farther from the Y-Axis have higher concentrations of Zn₁₋ₓMgₓO. Furthermore, cells that are closer to the X-Axis have higher concentrations of ZnO whereas cells farther from the X-Axis have higher concentrations of MgO. The number of located at the top of each cell is for identification of the cell.

In Table 1 below, the three-device average production of each location is described in terms of efficiency (Eff), fill factor (FF), and open circuit voltage (V_{oc}). The production of a reference cell is also included having an n-type partner only consisting of ZnO.

TABLE 1

| Location | Efficiency (%) | Fill Factor (%) | V_{oc} (mV) |
|---|---|---|---|
| ZnO Only N- | 4.83 | 50.65 | 789.18 |
| Type Reference | | | |
| 13 | 1.77 | 25.25 | 942.64 |
| 25 | 3.05 | 33.70 | 951.62 |
| 33 | 4.87 | 46.60 | 866.93 |
| 36 | 4.57 | 44.49 | 929.20 |
| 43 | 4.04 | 54.82 | 816.60 |
| 45 | 5.60 | 53.85 | 852.97 |
| 46 | 5.77 | 53.57 | 883.90 |
| 55 | 5.73 | 57.13 | 802.33 |
| 63 | 5.34 | 57.28 | 787.77 |

In Table 1, the locations most distant from the Y-Axis and between the MgO and ZnO guns produced the highest open circuit voltage (V_{oc}) and efficiency (Eff), namely locations 36 and 46. The Zn₁₋ₓMgₓO n-type partner produces much higher open circuit voltage (V_{oc}) as compared to traditional photovoltaic devices that use highly pure chalcogen absorber layer while preserving the photovoltaic cell efficiency.

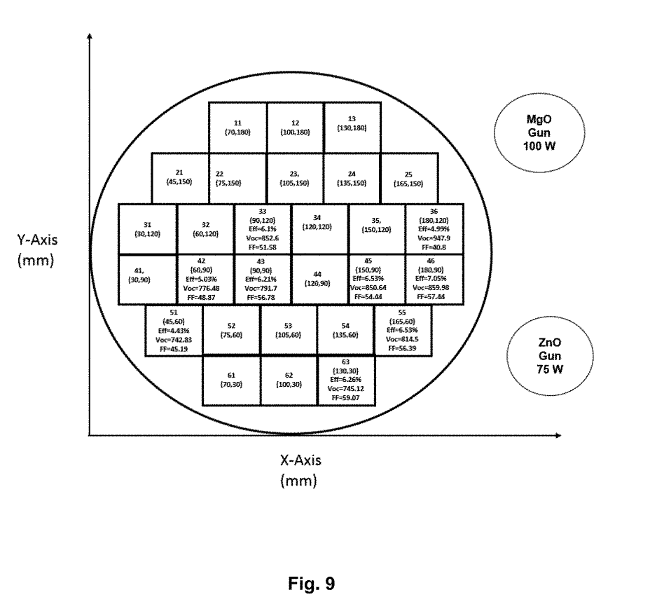

In FIG. 9, a diagram illustrating the characteristics of different photovoltaic cells with differing n-type partner compositions with aging is shown. Each individual square in the diagram shown in FIG. 9 represents a photovoltaic cell fabricated using the method provided in FIGS. 1-5. However, the deposition of the improved n-type partner varies from cell to cell. The cells closer to the Y-Axis have lower concentrations of Zn₁₋ₓMgₓO and the cells farther from the Y-Axis have higher concentrations of Zn₁₋ₓMgₓO. Furthermore, cells that are closer to the X-Axis have higher concentrations of ZnO whereas cells farther from the X-Axis have higher concentrations of MgO.

The devices were aged at least one month after the initial measurement and show a further increase in efficiency (Eff) and fill factor (FF). The number of located at the top of each cell is for identification of the cell. In Table 2 below, the aged three-device average production of each location is described in terms of efficiency (Eff), fill factor (FF), and open circuit voltage (V_{oc}).

TABLE 2

| Location | Efficiency (%) | Fill Factor (%) | V_{oc} (mV) |
|---|---|---|---|
| 33 | 6.10 | 51.58 | 852.60 |
| 36 | 4.99 | 40.80 | 947.90 |
| 42 | 5.03 | 45.19 | 742.83 |
| 43 | 6.21 | 56.78 | 791.70 |
| 45 | 6.53 | 54.44 | 850.64 |
| 46 | 7.05 | 57.44 | 859.98 |
| 51 | 4.43 | 45.19 | 742.83 |
| 55 | 6.53 | 56.39 | 814.50 |
| 63 | 6.26 | 59.07 | 745.12 |

In Table 2, the aged photovoltaic cells produced higher efficiency while preserving increased open circuit voltage (V_{oc}). Similar to Table 1, the locations most distant from the Y-Axis and between the MgO and ZnO guns produced the highest open circuit voltage (V_{oc}) and efficiency (Eff), namely locations 36 and 46. The aged photovoltaic devices with a Zn₁₋ₓMgₓO n-type partner produce much higher open circuit voltage (V_{oc}) as compared to traditional photovoltaic devices that use highly pure chalcogen absorber layer while preserving the photovoltaic cell efficiency.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A photovoltaic device, comprising:
a transparent substrate;
a transparent conductive electrode layer disposed on the transparent substrate;
an n-type layer of a compound having the formula Zn₁₋ₓMgₓO, wherein 0<x≦1, disposed on the transparent conductive electrode layer;
a chalcogen absorber layer disposed on the n-type layer; and
a conductive layer disposed on the chalcogen absorber layer.

2. The photovoltaic device according to claim 1, wherein the transparent conductive electrode layer is selected from the group consisting of: fluoride doped tin oxide (FTO), indium doped tin oxide (ITO), aluminum doped zinc oxide (ZnO:Al), and fluorine doped tin dioxide (SnO₂:F).

3. The photovoltaic device according to claim 1, wherein the n-type layer has a thickness from about 2 nm to about 200 nm.

4. The photovoltaic device according to claim 1, wherein the chalcogen absorber layer is selenium at a thickness from about 25 nm to about 200 nm.

5. The photovoltaic device according to claim 1, wherein a p-type molybdenum trioxide (MoO₃) interlayer is disposed between the chalcogen absorber layer and the conductive layer.

6. The photovoltaic device according to claim 1, wherein the conductive layer is selected from the group consisting of: carbon including graphite, graphene, nanotubes and combinations thereof.

7. The photovoltaic device according to claim 1, wherein the conductive layer is selected from the group consisting of: a metal, a metal alloy, gold, silver, copper, platinum, palladium; Zn, Ni, Co, Mo, Fe V, Cr, Sn, W, Mo, Ti, Mg, and combinations thereof.

8. The photovoltaic device according to claim 1, wherein the conductive layer is selected from the group consisting of: conductive oxides including fluoride doped tin oxide (FTO), indium doped tin oxide (ITO) and aluminum doped zinc oxide (ZnO:Al).

9. The photovoltaic device according to claim 1, wherein the conductive layer has a thickness of from about 2 nm to about 2000 nm.

10. The photovoltaic device according to claim 1, further comprising:
a tellurium (Te) adhesion layer disposed between the n-type layer and the chalcogen absorber layer.

11. The photovoltaic device according to claim 10, wherein the tellurium adhesion layer has a thickness of up to about 1 nanometer.

12. A method for fabricating a photovoltaic device, comprising the steps of:
forming a transparent conductive electrode layer on a transparent substrate;
forming an n-type layer of a compound having the formula Zn₁₋ₓMgₓO, wherein 0<x≦1, on the transparent conductive electrode layer;
forming a chalcogen absorber layer on the n-type layer;
forming a conductive layer on the chalcogen absorber layer; and
annealing at a temperature, pressure, and length of time sufficient to form the structure of the photovoltaic device.

13. The method according to claim 12, wherein the transparent conductive electrode layer is a material selected from the group consisting of: fluoride doped tin oxide (FTO), indium doped tin oxide (ITO) and aluminum doped zinc oxide (ZnO:Al).

14. The method according to claim 12, further comprising the step of:
forming a p-type interlayer of molybdenum trioxide (MoO₃) between the chalcogen absorber layer and the conductive layer.

15. The method according to claim 12, further comprising the step of:
forming a tellurium (Te) adhesion layer between the n-type layer and the chalcogen absorber layer.

16. A photovoltaic device, comprising:
a transparent superstrate;
a conductive layer disposed on the transparent superstrate;
a chalcogen absorber layer disposed on the conductive layer;
an n-type layer of a compound having the formula Zn₁₋ₓMgₓO, wherein 0<x≦1, disposed on the chalcogen absorber layer; and
a transparent conductive electrode layer disposed on the n-type layer.

17. The photovoltaic device according to claim 16, wherein the transparent conductive electrode layer is selected from the group consisting of: fluoride doped tin oxide (FTO), indium doped tin oxide (ITO), aluminum doped zinc oxide (ZnO:Al), and fluorine doped tin dioxide (SnO₂:F).

18. The photovoltaic device according to claim 16, wherein the n-type layer has a thickness from about 2 nm to about 200 nm.

19. The photovoltaic device according to claim 16, wherein the chalcogen absorber layer is selenium at a thickness from about 25 nm to about 200 nm.

20. The photovoltaic device according to claim 16, wherein a p-type molybdenum trioxide (MoO₃) interlayer is disposed between the conductive layer and the chalcogen absorber layer.

21. The photovoltaic device according to claim 16, wherein the conductive layer is selected from the group consisting of: carbon including graphite, graphene, nanotubes, and combinations thereof.

22. The photovoltaic device according to claim 16, wherein the conductive layer is selected from the group consisting of: a metal, a metal alloy, gold, silver, copper, platinum, palladium; Zn, Ni, Co, Mo, Fe V, Cr, Sn, W, Mo, Ti, Mg, and combinations thereof.

23. The photovoltaic device according to claim 16, wherein the conductive layer is selected from the group consisting of: conductive oxides including fluoride doped tin oxide (FTO), indium doped tin oxide (ITO) and aluminum doped zinc oxide (ZnO:Al).

24. The photovoltaic device according to claim 16, wherein the conductive layer has a thickness of from about 2 nm to 2000 nm.

25. The photovoltaic device according to claim 16, further comprising:
a tellurium (Te) adhesion layer disposed between the conductive layer and the chalcogen absorber layer.

26. The photovoltaic device according to claim 25, wherein the tellurium adhesion layer has a thickness of up to about 1 nanometer.

27. A method for fabricating a photovoltaic device, comprising the steps of:
forming a conductive layer on a transparent superstrate;
forming a chalcogen absorber layer on the conductive layer;
forming an n-type layer of a compound having the formula Zn₁₋ₓMgₓO, wherein 0<x<1, on the chalcogen absorber layer;
forming a transparent conductive electrode layer on the n-type layer; and
annealing at a temperature, pressure, and length of time sufficient to form the structure of the photovoltaic device.

28. The method according to claim 27, wherein the transparent conductive electrode layer is a material selected from the group consisting of: fluoride doped tin oxide (FTO), indium doped tin oxide (ITO) and aluminum doped zinc oxide (ZnO:Al).

29. The method according to claim 27, further comprising the step of:
forming a p-type molybdenum trioxide (MoO₃) interlayer between the conductive layer and the chalcogen absorber layer.

30. The method according to claim 27, further comprising the step of:
forming a tellurium (Te) adhesion layer between the p-type molybdenum trioxide (MoO₃) interlayer and the chalcogen absorber layer.
